(19) United States
(12) Patent Application Publication
(10) Pub. No.: US 2011/0103034 A1
(43) Pub. Date: May 5, 2011

(54) ELECTRONIC CHIP AND SUBSTRATE PROVIDING INSULATION PROTECTION BETWEEN CONDUCTING NODES

(76) Inventors: Yao-Sheng Huang, Kaohsiung City (TW); Ching-Jung Yang, Hsinchu City (TW)

(21) Appl. No.: 12/939,747

(22) Filed: Nov. 4, 2010

(30) Foreign Application Priority Data
Nov. 5, 2009 (TW) 098137546

(51) Int. Cl. H05K 7/00

(52) U.S. Cl. 361/820

(57) ABSTRACT

An electronic chip includes a plurality of conducting pins and a plurality of insulating blocks. The conducting pins are disposed on an outer side of the electronic chip to provide electrical connections between the electronic chip and an external circuit. Each of the insulating blocks is disposed between two adjacent conducting pins.

### BACKGROUND OF THE INVENTION

1. Field of the Invention

The present invention relates to an insulation technology of electronic products and more specifically to an electronic chip and a substrate having insulation protection between conducting pins.

2. Description of the Prior Art

In recent years, the technology progress allows various kinds of commercial, household and personal electronic products to be more and more popular. Other than becoming more powerful and having better appearance, the current trend of development in electronic products also includes reduction in volume and weight of those electronic products. The advances in manufacturing and packing technologies allow the area/volume of many electronic products to meet the above-mentioned light-weight requirement. However, the light-weight requirement also creates many new problems and challenges to the product designers and manufacturers.

Please refer to FIG. 1A to FIG. 1C, wherein FIG. 1A, FIG. 1B, and FIG. 1C are schematic views illustrating the spatial relationship between a conventional electronic chip and an external circuit coupled together with a conductive adhesive. The conducting pins 12 on the electronic chip 10 are used to provide electrical connections between the electronic chip 10 and the external circuit 16 (such as an electronic circuit board). For instance, the conducting pins 12 can be pins used to transmit data or voltages.

In practice, the material of conductive adhesive 14 includes resin materials having a lot of conductive particles 14A. As FIG. 1B shows, after the electronic chip 10, the conductive adhesive 14 and the external circuit 16 are coupled together, each conducting pin 12 will be electrically connected to the corresponding contacts 18 via the conductive particles 14A. Theoretically, conductive particles 14A between adjacent conducting pins 12 are not contacted with each other since no direct pressure is applied thereto and thus the adjacent conducting pins 12 are insulated from each other.

As mentioned above, the area/volume of the electronic chip is getting smaller and smaller. However, the number of conducting pins disposed on the electronic chop remains the same, and therefore the reduction in chip volume means that the area density of conducting pins will increase. Correspondingly, the distance between adjacent conducting pins will be smaller and this increase the possibility of adjacent conducting pins short-circuiting each other. In the situation illustrate in FIG. 1B, the distance between adjacent conducting pins 12 were previously 220 μm and is now reduced to approximately 15 μm. For the conductive particles 14A each having a diameter of 3 μm, the current length of gap between adjacent conductive pins 12 is now only the length of 5 to 6 conductive particles 14A aligned together.

Please refer to FIG. 1C, as the dotted area 19 shows, when the density of conductive particles 14A within the conductive adhesive 14 is high, the conductive particles 14A between two adjacent conducting pins 12 may be aligned to form a short-circuit between the two adjacent conducting pins 12. The above-mentioned short-circuit may cause malfunction or even burn-out within the electronic chip 10 or the external circuit 16.

### SUMMARY OF THE INVENTION

In order to solve the above-mentioned problem, the present invention discloses an electronic chip and a substrate to provide insulation protection between adjacent conductive pins or adjacent contacts.

One embodiment of the present invention relates to an electronic chip which includes a plurality of conducting pins and a plurality of insulating blocks. The electrical pins are disposed on an outer side of the electronic chip to provide electrical connections between the electronic chip and contacts of an external circuit. Each of the insulating blocks is disposed between two adjacent conducting pins.

One of the various embodiments of the present invention relates to a substrate which includes a plurality of contacts and a plurality of insulating blocks. The contacts are disposed on an upper surface of the substrate to provide electrical connections between the substrate and an electronic chip. Each of the insulating blocks is disposed between two adjacent contacts.

The concept of the present invention can be applied in different types of electronic chips and substrates. For a better understand of the advantages and spirit of the present invention, please refer to the explanation and figures disclosed below.

### BRIEF DESCRIPTION OF THE DRAWINGS

FIG. 1A, FIG. 1B, and FIG. 1C are schematic views illustrating the spatial relationship between a conventional electronic chip and an external circuit;

FIG. 2A, FIG. 2B, and FIG. 2C are schematic views illustrating an electronic chip according to a first embodiment of the present invention;

FIG. 3A and FIG. 3B are schematic views illustrating an electronic chip according to a second embodiment of the present invention;

FIG. 4A and FIG. 4B are schematic views illustrating the electronic chip of the present invention having a cushion pad;

FIG. 5A and FIG. 5B are schematic views illustrating an electronic chip according to a third embodiment of the present invention;

FIG. 6A and FIG. 6B are schematic views illustrating an substrate according to a fourth embodiment of the present invention; and

FIG. 7A and FIG. 7B are schematic views illustrating an electronic chip according to a fifth embodiment of the present invention.

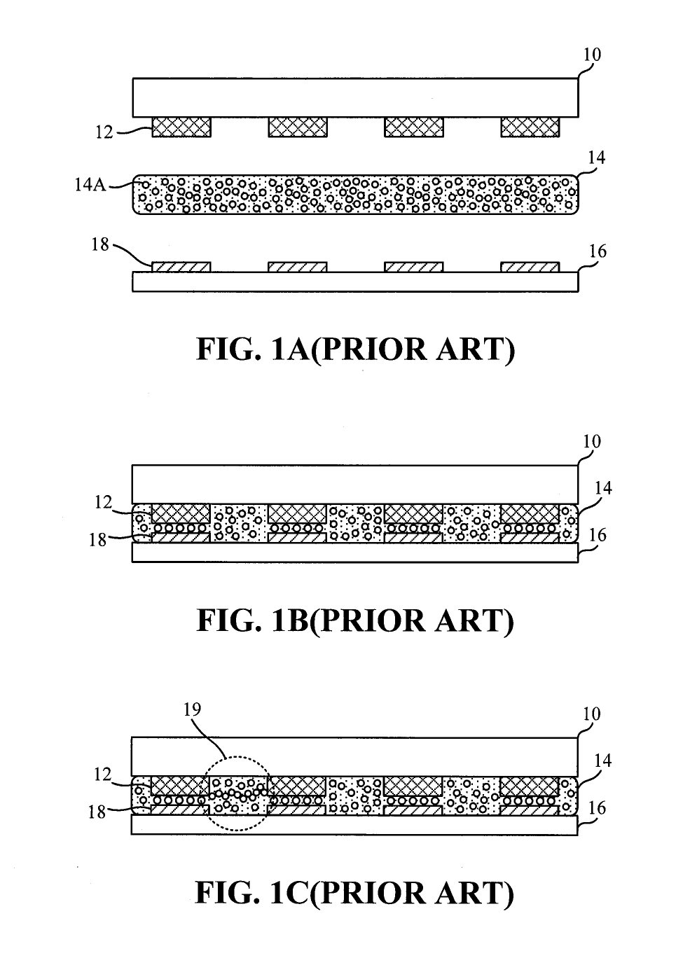

### DETAILED DESCRIPTION OF THE PREFERRED EMBODIMENT

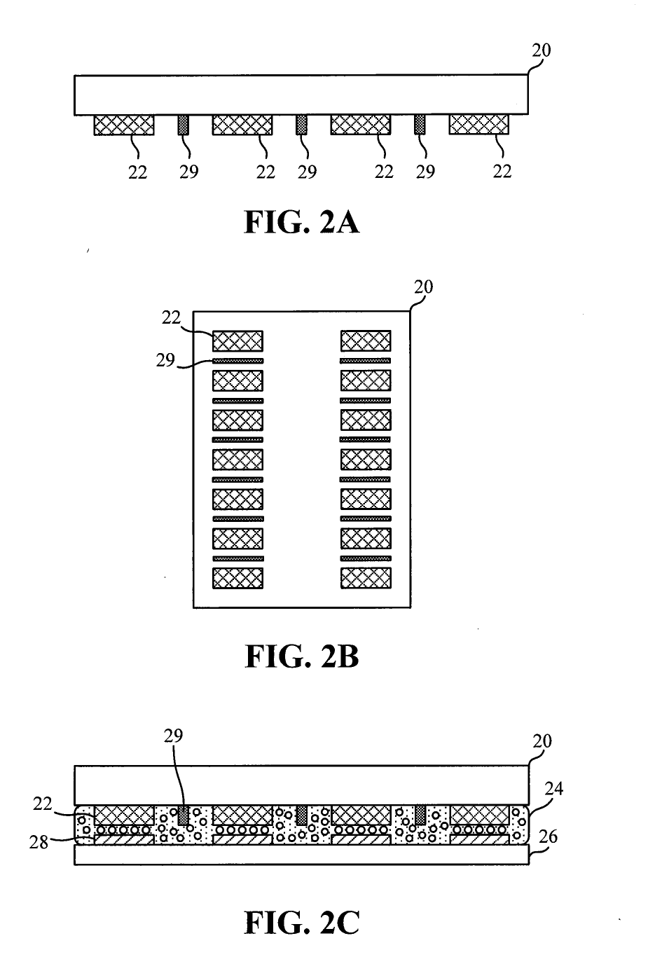

Please refer to FIG. 2A, wherein FIG. 2A is a schematic view illustrating an electronic chip according to a first embodiment of the present invention. The electronic chip 20 of the present embodiment includes a plurality of conducting pins 22 and a plurality of insulating blocks 29. The conducting pins 22 are disposed on an outer side of the electronic chip 20 and provide electronic connections between the electronic chip 20 and an external circuit. For instance, the conducting pins 12 can be pins used to transmit data or voltages.

The insulating blocks 29 are disposed between the conducting pins 22 adjacent to each other. In practice, the insulating block 29 can be made of polyimide or oxide materials formed on the outer side of the electronic chip 20 through an etching process.

In the present embodiment, the conducting pins 22 have an average height relative to the outer side of the electronic chip 20. The insulating blocks 29 have a second average height relative to the outer side of the electronic chip. The first average height is substantially equal to the second average height.

FIG. 2C is a schematic view illustrating a conductive adhesive 24 used to connect the electronic chip 20 with an external circuit 26. As FIG. 2C shows, the external circuit 26 (such as a rigid printed circuit board or a flexible printed circuit board) includes a plurality of contacts 28 used to be electrically connected to the conducting pins 22. After the electronic chip 20, the conductive adhesive 24 and the external circuit 26 are coupled together, each of the conducting pins 22 will be electrically connected to the corresponding contact 28 via conductive particles within the conductive adhesive 24. In practice, the conductive adhesive 24 can be anisotropic conductive adhesive (ACA), anisotropic conductive film (ACF) or other kinds of adhesives including conductive particles.

As FIG. 2C shows, after the electronic chip 20, the conductive adhesive 24 and the external circuit 26 are coupled together, the insulating blocks 29 between two adjacent conducting pins 22 create a barrier and reduce the possibility of the conductive particles connecting with each other. In other words, the insulating blocks 29 reduce the possibility of two adjacent conducting pins 22 short-circuiting each other.

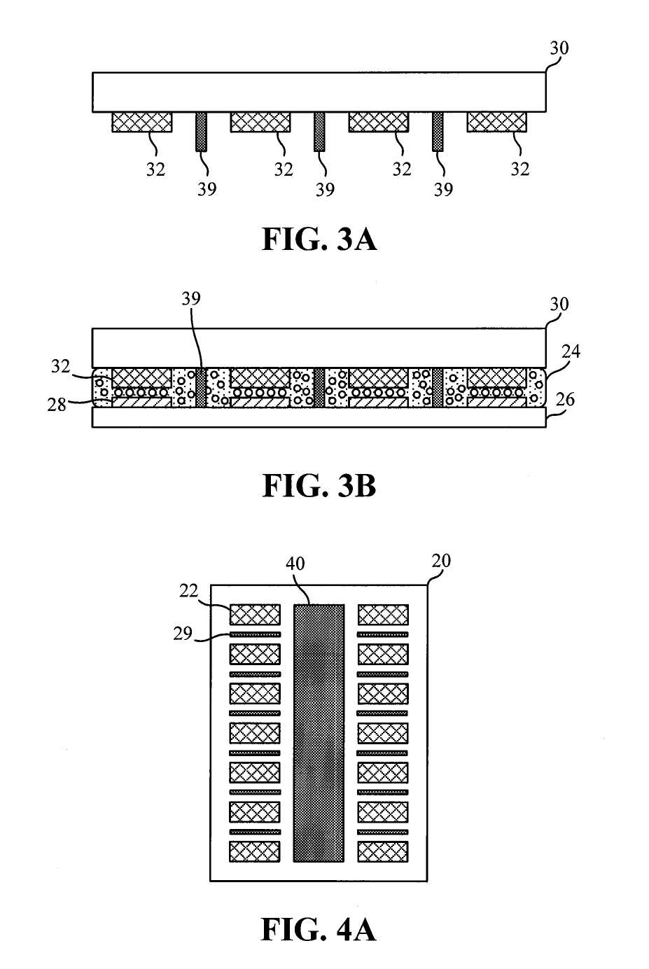

Please refer to both FIG. 3A and FIG. 3B. FIG. 3A is a schematic view of the electronic chip 30 according to a second embodiment of the present invention. FIG. 3B is a schematic view illustrating the connection between the electronic chip 30 and the external circuit 26. The electronic chip 30 includes a plurality of conducting pins 32 and a plurality of insulating blocks 39. In the present embodiment, the conducting pins 32 have a first average height relative the outer side of the electronic chip 30. The insulating blocks 39 have a second average height relative to the outer side of the electronic chip 30. The contacts 28 have a third average height relative to the upper surface of the external circuit 26. The second average height of the insulating blocks 39 are substantially equal to the sum of the first average height of the conducting pins 32 and the third average height of the contacts 28.

As FIG. 3B shows, after the electronic chip 30, the conductive adhesive 24 and the external circuit 26 are coupled together, the insulating block 39 almost completely insulates two adjacent conducting pins 32, thus excluding almost completely the chance of conductive particles of the conductive adhesive 24 connecting each other within the gap between the insulating block 39 and the electronic chip 30/external circuit 26. In other words, the insulating blocks 39 substantially exclude the possibility of the conducting pins 32 short-circuiting each other.

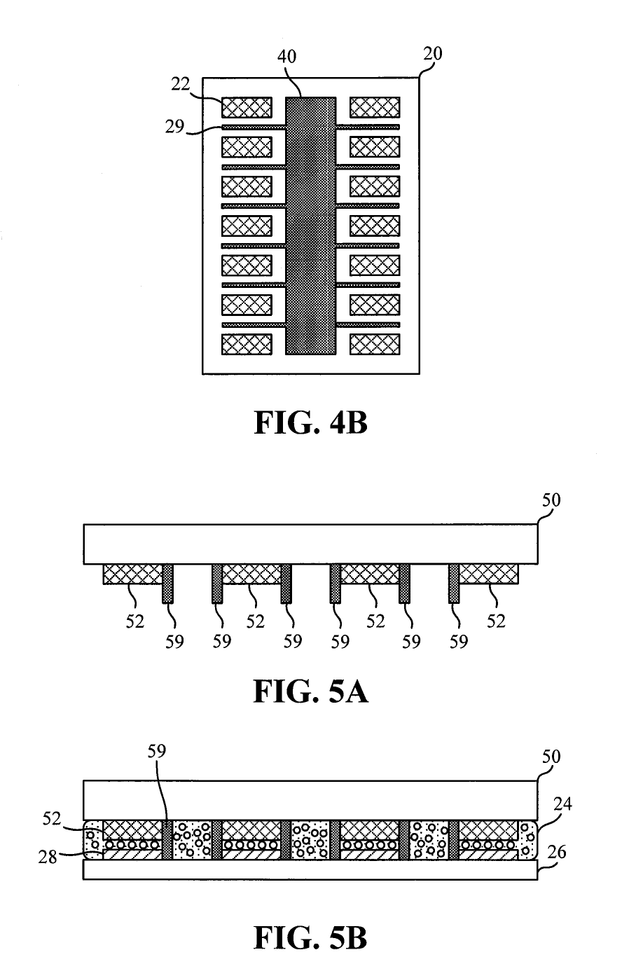

Please refer to FIG. 4A illustrating the electronic chip 20 according to the first embodiment but having an additional cushion pad 40. The cushion pad 40 is disposed on the outer side of the electronic chip 20. The cushion pad 40 can absorb shock before or after the electronic chip 20 is attached to the external circuit 26 and thus prevent the electronic chip 20 from damages due to friction or collision.

In practice, the cushion pad 40 and the insulating blocks 29 are both made of polyimide with insulation characteristics. In this way, the cushion pad 40 and the insulating blocks 29 can be formed on the outer side of electronic chip 20 through the same process. As FIG. 4B shows, other than the identical materials, the insulating pins 29 and the cushion pad 40 can be connected with each other in other designs.

FIG. 5A is a schematic view of the electronic chip 50 according to a third embodiment of the present invention. The electronic chip 50 of the present embodiment includes a plurality of conducting pins 52 and a plurality of insulating blocks 59. The difference between electronic chip 50 of the present embodiment and that of the previous embodiment is that each insulating block 59 is immediately adjacent to one side of the conducting pin 52. As FIG. 5B shows, the above-mentioned design can also provide the adjacent conducting pins with insulation protection.

In practice, when the electronic chip and the external circuit are not connected using conductive adhesive, the insulating blocks of the present invention can still be used to prevent adjacent conducting pins from short-circuiting each other. For instance, the electronic chip and the external circuit can be connected through soldering, and the insulating blocks according to the present invention can be used to prevent the adjacent conducting pins from short-circuiting each other.

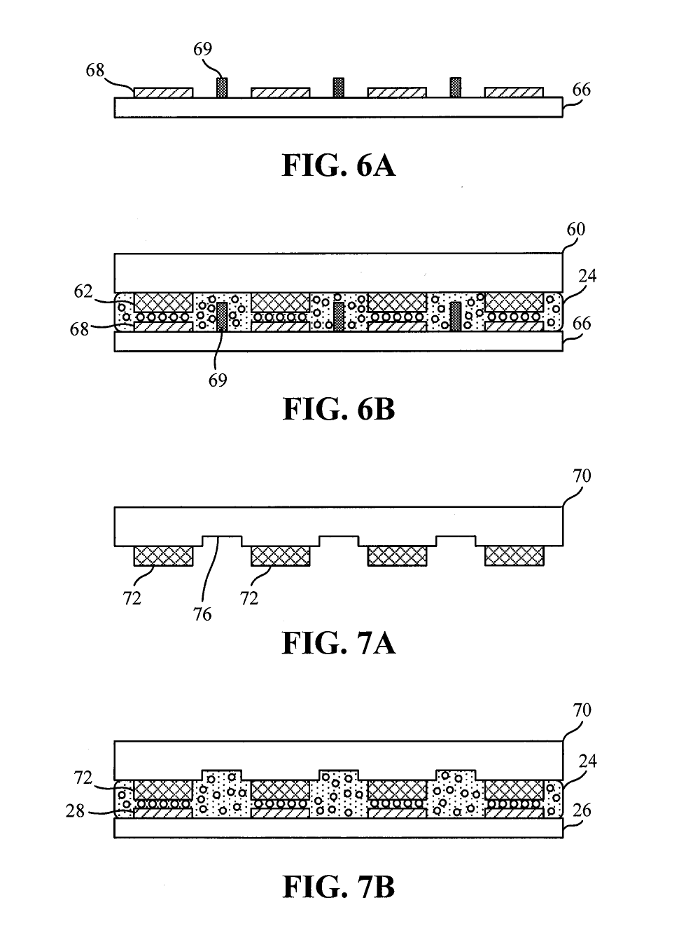

A fourth embodiment of the present invention relates to a substrate. As FIG. 6A shows, the substrate 66 includes a plurality of contacts 68 and a plurality of insulating blocks 69. The contacts 68 are disposed on an upper surface of the substrate 66 to provide electrical connections between the substrate 66 and an electronic chip. Each of the insulating blocks 69 is disposed between two adjacent contacts 68. In practice, the insulating blocks 69 can be made of polyimide or other insulating materials.

As FIG. 6B shows, after the electronic chip 60, the conductive adhesive 64 and the substrate 66 are coupled together, the insulating blocks 69 will create barrier between adjacent conducting pins 62 and adjacent contacts 68. In this way, the insulating blocks 69 substantially exclude the chance of conductive particles of the conductive adhesive 24 connecting each other within the gap between the insulating block 69 and the substrate 66/electronic chip 60. Therefore, the insulating blocks 69 reduce the chance of adjacent conducting pins 69 or adjacent contacts 68 short-circuiting each other.

In the present embodiment, the insulating blocks 69 are slightly taller than the contacts 68. However, the insulating blocks 69 and the contacts 68 can be substantially equal in height. Preferably, the height of insulating blocks 69 can be equal to a sum of the height of contact 68 and that of the corresponding conducting pin 62. Furthermore, in practice, the insulating blocks 69 can be placed immediately adjacent to at least one side or both sides of the contacts 68.

A fifth embodiment of the present invention relates to an electronic chip. Please refer to FIG. 7A which is a schematic view of the electronic chip 70 of the present embodiment. The electronic chip 70 of the present embodiment includes a plurality of conducting pins 72 and a plurality of notches 76. The conducting pins 72 are disposed on an outer side of the electronic chip 70 to provide electrical connections between the electronic chip 70 and contacts of an external circuit. Each of the notches 76 is formed between two adjacent conducting pins 72. The similarity between the electronic chip 70 of the present embodiment and those of the previous embodiment is that the conducting pins 72 are electrically connected to the external circuit through a conductive adhesive.

In practice, the notches 76 are formed on the outer side of electronic chip 70 through an etching process. As FIG. 7A shows, the depression region of each notch 76 is lower than a reference surface of the outer side. FIG. 7B is a schematic view illustrating the connection between the electronic chip 70 and the external circuit 26 through the conductive adhesive 24. As FIG. 7B shows, after the electronic chip 70, the conductive adhesive 24 and the external circuit 26 are coupled together, each of the notches 76 will provide a greater space between two adjacent conducting pins 72 to accommodate the conductive particles of the conductive adhesive 24. In this way, the notches 76 reduce the possibility of the conductive particles electrically connected with each other and thus provide similar effect of using the insulating blocks.

As mentioned above, the insulating blocks or notches of the present invention can be used to reduce the possibility of adjacent conductive pins short-circuiting each other and prevent the electronic chip from damages due to short-circuit. Furthermore, the concept of the present invention can be applied to different types of electronic chips and substrates in order to provide good insulation protection.

The above is a detailed description of the particular embodiment of the invention which is not intended to limit the invention to the embodiment described. It is recognized that modifications within the scope of the invention will occur to a person skilled in the art. Such modifications and equivalents of the invention are intended for inclusion within the scope of this invention.

What is claimed is:

1. An electronic chip, comprising:
a plurality of conducting pins disposed on an outer side of the electronic chip and used to provide electrical connections between the electronic chip and an external circuit; and
a plurality of insulating blocks disposed between the conducting pins adjacent to each other.

2. The electronic chip of claim 1, wherein the conducting pin is electrically connected to the external circuit through a conductive adhesive.

3. The electronic chip of claim 1, wherein the conducting pins have a first average height relative to the outer side, the insulating blocks have a second average height relative to the outer side, the first average height is substantially equal to the second average height.

4. The electronic chip of claim 1, wherein the external circuit includes a plurality of contacts used to be electrically connected to the conducting pins, the conducting pins have a first average height relative to the outer side, the insulating blocks include a second average height relative to the outer side, the contacts include a third average height relative to an upper surface of the external circuit, the second average height is substantially equal to a sum of the first average height and the third average height.

5. The electronic chip of claim 1, wherein a material of the insulating block includes polyimide materials.

6. The electronic chip of claim 1, wherein a material of the insulating blocks includes oxide materials, the insulating blocks are formed on the outer side of the electronic chip through an etching process.

7. The electronic chip of claim 1, further including a cushion pad disposed on the outer side, the insulating blocks and the cushion pad are connected and made of the same material.

8. The electronic chip of claim 1, wherein the insulating blocks are directly connected to at least one side of one of the conducting pins.

9. A substrate, comprising:
a plurality of contacts disposed on an upper surface of the substrate and used to provide electrical connections between the substrate and an electronic chip; and
a plurality of insulating blocks disposed between the contacts adjacent to each other.

10. The substrate of claim 9, wherein the contact is electrically connected to the electronic chip through a conductive adhesive.

11. The substrate of claim 9, wherein the contacts have a first average height relative to the upper surface, the insulating blocks have a second average height relative to the upper surface, the first average height is substantially equal to the second average height.

12. The substrate of claim 9, wherein the electronic chip includes a plurality of conducting pins used to be electrically connected to the contacts, the contacts have a first average height relative to the upper surface, the insulating blocks include a second average height relative to the upper surface, the conducting pins include a third average height to an outer side of the electronic chip, the second average height is substantially equal to a sum of the first average height and the third average height.

13. The substrate of claim 9, wherein a material of the insulating block includes polyimide materials.

14. The substrate of claim 9, wherein the insulating blocks are directly connected to at least one side of one of the contacts.

15. An electronic chip, comprising:
a plurality of conducting pins disposed on an outer side of the electronic chip and used to provide electrical connections between the electronic chip and an external circuit; and
a plurality of notches formed between the conducting pins adjacent to each other, at least one depression region of one of the notches is lower in height than a reference surface of the outer side.

16. The electronic chip of claim 15, wherein the conducting pin is electrically connected to the external circuit through a conductive adhesive.

17. The electronic chip of claim 15, wherein the notches are formed on the outer side of the electronic chip through an etching process.
